(19) United States
(12) Patent Application Publication
(10) Pub. No.: US 2013/0160821 A1
(43) Pub. Date: Jun. 27, 2013

(54) Method for Producing a Solar Energy Conversion Module and a Module Produced by Same

(71) Applicant: Halil Ibrahim Dag, Meram / Konya (TR)

(72) Inventor: Halil Ibrahim Dag, Meram / Konya (TR)

(73) Assignee: Solimpeks Enerji Sanayi Ve Ticaret A.S.

(21) Appl. No.: 13/698,646

(22) PCT Filed: Apr. 25, 2011
(86) PCT No.: PCT/TR2011/000101

§ 371 Date: Feb. 25, 2013

(30) Foreign Application Priority Data
May 18, 2010 (TR) 2010/03923

(51) Int. Cl. H01L 31/052; H01L 31/18

(52) U.S. Cl. CPC H01L 31/052; H01L 31/18
USPC 136/248; 438/66

(57) ABSTRACT

The invention relates to a method for producing a PV/T type hybrid solar energy conversion module having a thermal unit associated with a photovoltaic unit for providing heat transfer from the photovoltaic unit comprising a number of solar cells (5). The method comprises laminating the photovoltaic unit and thermal unit to one another via at least one EVA (Ethylene-vinyl acetate) layer or PVB (Polyvinyl Butyral) or an EVA or PVB-based layer.

### TECHNICAL FIELD

Present invention relates to a method for producing a so-called “PV/T” type hybrid solar energy conversion module comprising photovoltaic and thermal units and a module produced by this method.

### BACKGROUND OF INVENTION

One of the major reasons for the electricity generation from solar energy systems not to become widely available is that ambient temperature increase cause to decrease PV module's efficiency which lengthens the return of the investment on those systems even though it is very easy to find a PV module manufacturer. It is possible to reduce PV module temperature using fluid circulation. Recently, to increase PV module efficiency and search for an alternative to stand alone PV module usage, the studies have been performed on the PV/Thermal (PV/T) systems which generate electricity and heat energy at the same time and further cool down PV module.

For example, U.S. Pat. No. 5,522,944 discloses a PV/T type solar energy conversion module which is unsealed enclosure having a cover, a frame including a back wall, a plurality of side walls, and a flange adapted to receive said cover, with said cover being loosely clamped within said flange; an array of photovoltaic cells for converting solar energy impinging thereon to electrical energy located within the enclosure to provide a source of electrical power; a plurality of interconnected heat collecting tubes located within the enclosure and disposed on the same plane as the array of photovoltaic cells for converting solar energy impinging thereon to thermal energy in a fluid disposed within the heat collecting tubes to provide a source of thermal energy.

The way of the PV and the T units integration of each other within the case and said integration material's thermal, mechanical, corrosion, adhesion etc. properties have a great impact on PV unit efficiency and on the final module efficiency. As a matter of fact, because of performance of PV module efficiency decreases when ambient temperature goes up an effective heat transfer mechanism is needed. Moreover, the thermal stresses between the units against the varying temperatures should be tolerated in a proper way and furthermore the PV/T module should be resistant enough against possible mechanical strain.

### DESCRIPTION OF INVENTION

The aim of the present invention is to increase rate of electricity generation from the PV/T type hybrid solar energy conversion module proportionally.

Another aim of the present invention is to increase the PV/T type hybrid solar energy conversion module's ultimate efficiency.

Another aim of the present invention is to increase the PV/T type hybrid solar energy conversion module's life time.

Another aim of the present invention is to increase the PV/T type hybrid solar energy conversion module's mechanical resistance.

The invention proposes a method to produce a PV/T type hybrid solar energy conversion module having a thermal unit associated with a photovoltaic unit for providing heat transfer from the photovoltaic unit comprising a number of solar cells. According to the method, photovoltaic unit and thermal unit are laminated to each other via at least one layer of EVA (Ethylene-vinyl acetate), PVB (Polyvinyl Butyral) or one layer of EVA or PVB based material.

EVA, PVB or EVA or PVB based lamination layer which is used in the method of the invention can be located between top glass and PV unit and beneath thermal unit besides between PV unit and thermal unit.

According to a preferred configuration of the invention, PV and thermal units are laminated each other via the existence of EVA, PVB or EVA or PVB based lamination layer preferably by vacuum lamination process.

### DESCRIPTION OF FIGURES

Main components which constitute the PV/T type hybrid solar energy conversion module obtained by the method of the invention are shown in FIG. 1 in exploded perspective view.

The module in FIG. 1 which is assembled perspective view is shown in FIG. 2.

FIG. 3 is a front view of FIG. 2.

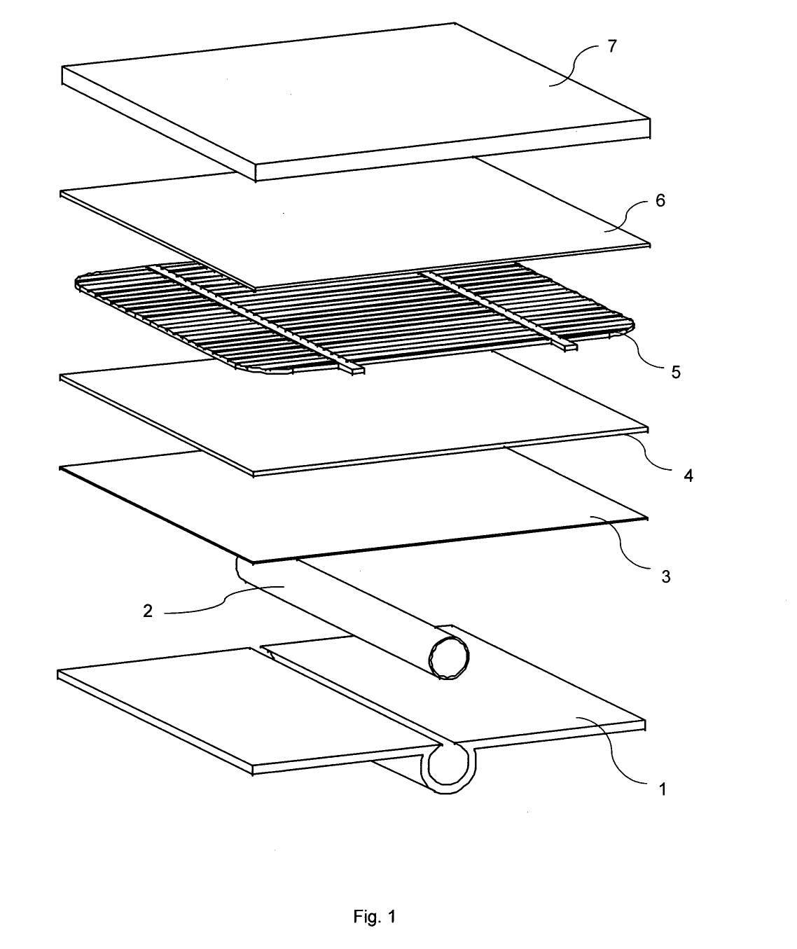

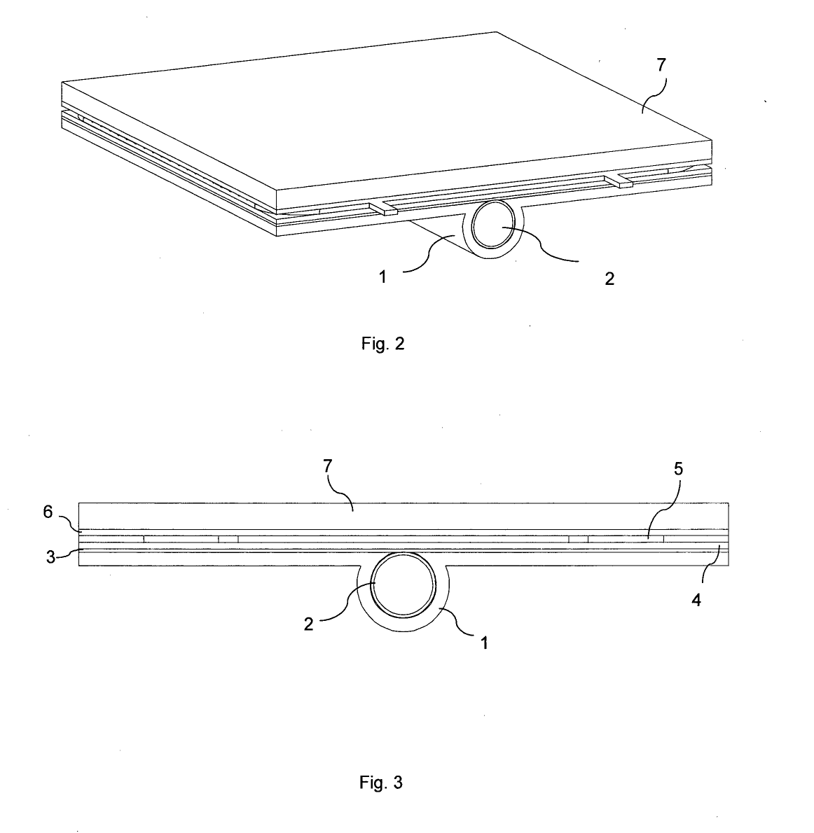

### REFERENCE NUMBERS

1 Bottom layer

2 Pipe

3 Heat transfer plate

4 Layer

5 Solar cells

6 Upper layer

7 Glass

### DETAILED DESCRIPTION OF INVENTION

The PV/T type hybrid solar energy conversion module of the invention essentially comprises from bottom-up, a bottom layer (1) preferably made of an EVA (Ethylene-vinyl acetate) or PVB (Polyvinyl Butyral) or made of EVA or PVB-based material, a pipe (2) through which fluid flows and the bottom side of which is wrapped by the bottom layer (1), a heat transfer plate (3) to which said pipe (2) is connected, EVA or PVB or EVA or PVB-based layer (4), solar cells (5), EVA or PVB or EVA or PVB-based material upper layer (6), and top of this layer a glass (7).

The PV/T type hybrid solar energy conversion module of the invention comprises the following steps of:
connecting solar cells to one another to constitute an array,
preparing and locating an EVA layer or a PVB layer,
locating solar cells on the EVA layer or PVB layer, and locating an upper layer made of EVA or PVB layer on the solar cells,
locating a thermal unit at the bottom of the EVA layer or PVB layer,
locating a bottom layer (1) made of an EVA layer or a PVB layer at the bottom of the thermal unit,
locating a glass on the upper layer made of an EVA layer or a PVB material,
subjecting the above layers and units to a lamination process at an appropriate lamination temperature.

While the photovoltaic unit (PV unit) of the PV/T module of the invention comprises solar cells, the thermal unit (T unit) of it is preferably consist of the copper pipe (2) which fluid flows through and the heat transfer plate (3) to which the pipe is connected. The pipe (3) and heat transfer plate (3) is connected to one another preferably via ultrasonic or laser welding process. The heat transfer plate (3) is preferably made of copper material, but it can also be made of aluminum or stainless steel. Further, the pipe (2) can be made of aluminum or stainless steel.

Lamination process is performed by preferably vacuum lamination method. To accomplish this vacuum laminator whose flexible membranes are separated within vacuum chamber which is known from the art.

After the lamination process, the module is placed inside a case and then its mount operations are completed.

The solar energy conversion module of the invention may comprise an additional layer to be placed between the solar cells (5) and the layer (4). The material of this additional layer is selected from the group consisting of glass, a layer consisting of polyvinyl fluoride and a polyester film, and Polytetrafluoroethylene. The additional layer provides structural strength of the module as it prevents solar cells (5) from breaking caused by external impacts. Further, heat transfer is reduced by providing the additional layer therefore electricity performance of the module is enhanced. Moreover, in case of glass, the additional layer provides the advantage of integrating a ready-to-use PV module with the rest of the PV/T module disclosed above.

Furthermore, the bottom layer (1) of the PV/T module of the invention can be covered underside by a heat-seal layer for isolating the module.

1. A method for producing a PV/T type hybrid solar energy conversion module, wherein the module comprises a thermal unit having pipes (2) through which fluid is flown and a heat transfer plate (3) connected to the pipes (2);
and a photovoltaic unit having a number of solar cells (5) for transferring heat to the thermal unit;
comprising the following steps of:
connecting the solar cells (5) to one another to constitute an array,
preparing and locating an EVA layer or a PVB layer (4),
locating the solar cells (5) on the EVA layer or PVB layer (4), and locating an upper layer (6) made of EVA or PVB layer on the solar cells (5),
locating the thermal unit at the bottom of the EVA layer or PVB layer (4),
locating a bottom layer (1) made of an EVA layer or a PVB layer (1) at the bottom of the thermal unit,
locating a glass (7) on the upper layer (6) made of an EVA layer or a PVB material,
subjecting the above layers and units to a lamination process at an appropriate lamination temperature.

2. A method according to claim 1, wherein the pipes (2) are made of copper, aluminum or stainless steel and being directly connected to the heat transfer plate (3) made of copper, aluminum or stainless steel.

3. A method according to claim 2, wherein the pipes (2) are connected to the heat transfer plate (3) via ultrasonic or laser welding.

4. A method according to claim 1, wherein the lamination process is performed via a vacuum laminator.

5. A method according to claim 1, further comprising providing an additional layer between the solar cells (5) and the layer (4), wherein the material of the additional layer is selected from the group consisting of glass, a layer consisting of polyvinyl fluoride and a polyester film, and Polytetrafluoroethylene.

6. A PV/T type hybrid solar energy conversion module comprising a thermal unit having pipes (2) through which fluid is flown and a heat transfer plate (3);
a photovoltaic unit having a number of solar cells (5) for transferring heat to the thermal unit,
characterized in that the module comprises a bottom layer (1) made of EVA or PVB layer, the bottom layer (1) wrapping the bottom side of the pipes (2) and heat transfer plate (3),
an EVA or a PVB layer (4) being provided at the upper side of the heat transfer plate (3), the solar cells (5) being provided on to this layer (4), an upper layer (6) made of an EVA or a PVB layer being provided on the solar cells (5), and a glass (7) provided on to the upper layer (6).

7. A solar energy conversion module according to claim 6, wherein the pipes (2) are made of copper, aluminum or stainless steel and being directly connected to the heat transfer plate (3) made of copper, aluminum or stainless steel.

8. A solar energy conversion module according to claim 7, wherein the pipes (2) are connected to the heat transfer plate (3) via ultrasonic or laser welding.

9. A solar energy conversion module according to claim 6, wherein elements of the module is laminated to one another via a vacuum laminator.

10. A solar energy conversion module according to claim 6, further comprising providing an additional layer between the solar cells (5) and the layer (4), wherein the material of the additional layer is selected from the group consisting of glass, a layer consisting of polyvinyl fluoride and a polyester film, and Polytetrafluoroethylene.
